(19) United States
(12) Patent Application Publication
(10) Pub. No.: US 2026/0223488 A1
(43) Pub. Date: Jul. 30, 2026

(54) METHOD FOR MANUFACTURING CHIPS ON WAFER FOR MICRO LED DISPLAY

(71) Applicant: WAVELORD CO., LTD, Hwaseong-si (KR)

(72) Inventors: Juneo SONG, Suwon-si (KR); Ji Hyung MOON, Gunpo-si (KR)

(73) Assignee: WAVELORD CO., LTD, Hwaseong-si (KR)

(21) Appl. No.: 19/145,902

(22) PCT Filed: Aug. 13, 2024
(86) PCT No.: PCT/KR2024/012079

§ 371 Date: Jul. 4, 2025

(30) Foreign Application Priority Data
Sep. 5, 2023 (KR) 10-2023-0117750

(51) Int. Cl. H10H 20/01

(52) U.S. Cl. CPC H10H 20/019; H10H 20/0133

(57) ABSTRACT

The present invention relates to, in manufacturing, by using a chip on wafer method, a lateral chip, a flip chip, and a vertical chip for a micro LED display, a method for manufacturing chips on wafer for a micro LED display, in which, by molding an undoped semiconductor area to a desired thickness without chip damage, high-quality chips of 3 μm or less for high-luminance micro LED displays may be manufactured.

### TECHNICAL FIELD

The present invention relates to a method of manufacturing a chip-on-wafer for a micro-light-emitting diode (LED) display, and more particularly, to a method of manufacturing a chip-on-wafer for a micro-LED display, which can manufacture high-quality and high-brightness micro-LED display chips having a thickness of 3 μm or less by forming an un-doped semiconductor region (e.g., uGaN, uInGaN, uAlGaN, uAlGaInN, uGaP, uInGaP, uAlGaP, or uAlGaInP) to a desired thickness without damaging the chips, in manufacturing lateral chips, flip chips, and vertical chips for a micro-LED display using a chip-on-wafer method.

### BACKGROUND ART

In general, micro-light-emitting diode (LED) displays (including mini LED displays) can be classified into micro-LED displays using a passive matrix (PM) driving method and micro-LED displays using an active matrix (AM) driving method.

Here, PM-driven micro-LED displays typically have a sapphire support substrate, which finally remains, and use sorted thick blue, green, and red (BGR) chips (both the positive electrode and negative electrode of the LED are fully manufactured), which are transferred using a chip die-level process in which either horizontal chips or flip chips can be generally used.

In addition, AM-driven micro-LED displays typically do not have a sapphire support substrate, which finally remains, and use unsorted thin blue, green, and red (BGR) chips (both the positive electrode and negative electrode of the LED are fully manufactured), which are transferred using a wafer-level process in which horizontal chips, flip chips, or vertical chips can all be generally used.

Recently, there has been an increasing demand for smaller-sized chips for the manufacture of micro-scale LED displays. In response to such market demand, micro-LED display chips currently being manufactured generally have a thickness in the range of 5 μm to 7 μm, but, achieving a thickness of less than 5 μm is considered difficult due to issues such as chip breakage.

Meanwhile, a chip-on-wafer method refers to a method in which the entire process, from the epitaxial growth of a semiconductor layer on an initial growth substrate to the final fabrication (fab) process, is performed on the initial growth wafer.

According to such a conventional chip-on-wafer method, since a stacked structure of the chip is completed using only the initial growth substrate, a thickness of an un-doped semiconductor region (e.g., uGaN) or an n-type semiconductor region (e.g., nGaN) cannot be adjusted. As a result, it is difficult to manufacture micro-LEDs with a thickness of 5 μm or less, and the presence of such a thick un-doped semiconductor region (e.g., uGaN, uInGaN, uAlGaN, uAlGaInN, uGaP, uInGaP, uAlGaP, or uAlGaInP) leads to a reduction in light extraction efficiency.

Meanwhile, in the conventional chip-on-wafer method, the completed chip may be attached to a thin film transistor (TFT) glass, an interposer, or the like, and then the initial growth substrate on the opposite side may be removed to expose the un-doped semiconductor region (e.g., uGaN, uInGaN, uAlGaN, uAlGaInN, uGaP, uInGaP, uAlGaP, or uAlGaInP), but, even when attempting to etch the exposed un-doped semiconductor region (e.g., uGaN, uInGaN, uAIGaN, uAlGaInN, uGaP, uInGaP, uAlGaP, or uAlGaInP), the completed chip may be damaged due to high temperatures and injected gases generated during the etching process.

Furthermore, when the initial growth substrate is removed by a laser lift-off (LLO) process, numerous gallium (Ga) droplets (solid or powder) that interfere with the scattering of generated light are generated on the surface of the semiconductor layer from which the initial growth substrate has been removed. Currently, hydrochloric acid vapor or taping is used to remove the gallium (Ga) droplets, but, when the hydrochloric acid vapor is used, there are issues that the process results in excessively high costs and the chip can be damaged during the gallium (Ga) droplet removal process, and when the taping is used, there is an issue that complete removal of the gallium (Ga) droplets is not possible. However, in the case of removing the growth substrate for micro-LEDs using a chemical lift-off (CLO) process, such as Si (nitrides emitting blue, green, and red light) or GaAs (phosphides emitting red light), there is no issue related to the gallium (Ga) droplets.

In addition, according to the conventional chip-on-wafer method, since the stacked structure of the chip is completed using only the initial growth substrate, an ohmic contact electrode is inevitably formed in a back-end process. In this case, the formation of the ohmic contact electrode essentially requires heat treatment at a temperature of 300° C. or higher, and thus there is an issue that the chip, in which a plurality of layers are already stacked, may be damaged by the high temperature.

### DISCLOSURE

### Technical Problem

The present invention is directed to solving the above-mentioned conventional problems and providing a method of manufacturing a chip-on-wafer for a micro-light-emitting diode (LED) display, which can manufacture high-quality and high-brightness micro-LED display chips having a thickness of 3 μm or less by forming an un-doped semiconductor region (e.g., uGaN, uInGaN, uAlGaN, uAlGaInN, uGaP, uInGaP, uAlGaP, or uAlGaInP) to a desired thickness without damaging the chip in manufacturing lateral chips, flip chips, and vertical chips for a micro-LED display using a chip-on-wafer method.

### Technical Solution

The above objective is achieved, according to the present invention, by a method of manufacturing a chip-on-wafer for a micro light-emitting diode (LED) display, the method including a growth operation of epitaxially growing a semiconductor layer on a growth substrate, an electrode formation operation of forming an ohmic contact electrode on the semiconductor layer, an adhesion operation of bonding the ohmic contact electrode to a temporary substrate through an adhesive layer, an exposure operation of exposing one surface of the semiconductor layer by removing the growth substrate, a bonding operation of bonding the exposed one surface of the semiconductor layer to a support substrate, and a removal operation of removing the temporary substrate and the adhesive layer.

Further, the method may further include a forming operation of etching the exposed one surface of the semiconductor layer to form the semiconductor layer to a predetermined thickness.

Further, in the growth operation, a third semiconductor region, a second semiconductor region, an active region, and a first semiconductor region may be epitaxially grown in sequence, in the forming operation, the third semiconductor region, which is exposed, may be etched to form the semiconductor layer to the predetermined thickness, and the third semiconductor region may be an un-doped semiconductor region.

Further, the method may further include a reflective layer formation operation of forming a reflective layer on the exposed one surface of the semiconductor layer, wherein, in the bonding operation, the one surface of the semiconductor layer on which the reflective layer is formed may be bonded to the support substrate through a bonding layer.

Further, the reflective layer may be in ohmic contact with the one surface of the semiconductor layer.

Further, in the bonding operation, the one surface of the semiconductor layer may be bonded to the support substrate through a bonding layer.

Further, the bonding layer may be in ohmic contact with the one surface of the semiconductor layer.

Further, in the bonding operation, after a separation layer is formed on the support substrate, the one surface of the semiconductor layer may be bonded to the separation layer.

Further, in the adhesion operation, after a separation layer is formed on the temporary substrate, the ohmic contact electrode may be bonded to the separation layer through the adhesive layer.

Further, in the adhesion operation, after a protective layer is formed on the ohmic contact electrode, the protective layer may be bonded to the temporary substrate through the adhesive layer.

### Advantageous Effects

According to the present invention, in the manufacture of lateral chips, flip chips, and vertical chips for a micro-light-emitting diode (LED) display using a chip-on-wafer method, an un-doped semiconductor region (e.g., uGaN, uInGaN, uAlGaN, uAlGaInN, uGaP, uInGaP, uAlGaP, or uAlGaInP) can be formed to a desired thickness without damaging the chip, thereby enabling the manufacture of high-quality and high-brightness micro-LED display chips having a thickness of 3 μm or less, and fundamentally preventing the issue of gallium (Ga) droplets remaining on a surface of a semiconductor layer, which significantly improves light extraction efficiency.

In addition, according to the present invention, after a semiconductor layer is grown, an ohmic contact electrode is formed through high-temperature heat treatment in a state in which no other layers are stacked, and then the remaining necessary layers, such as a reflective layer, are stacked on the surface of the semiconductor layer, so that damage to the chip having stacked layers caused by the high-temperature heat treatment during the formation of the ohmic contact electrode can be fundamentally prevented.

Meanwhile, the effects of the present invention are not limited to the above-mentioned effects, and various effects may be included within the scope which is apparent to those skilled in the art from contents to be described below.

### BRIEF DESCRIPTION OF DRAWINGS

FIGS. 1 and 2 illustrate an overall process in which a chip-on-wafer is manufactured according to a method of manufacturing a chip-on-wafer for a micro-light-emitting diode (LED) display of the present invention.

FIG. 3 is a flowchart of a method of manufacturing a chip-on-wafer for a micro-LED display according to a first embodiment of the present invention.

FIG. 4 illustrates a process in which a chip-on-wafer is manufactured in accordance with the method of manufacturing a chip-on-wafer for a micro-LED display according to the first embodiment of the present invention.

FIG. 5 is a flowchart of a method of manufacturing a chip-on-wafer for a micro-LED display according to a second embodiment of the present invention.

FIG. 6 illustrates a process in which a chip-on-wafer is manufactured in accordance with the method of manufacturing a chip-on-wafer for a micro-LED display according to the second embodiment of the present invention.

FIG. 7 is a flowchart of a method of manufacturing a chip-on-wafer for a micro-LED display according to a third embodiment of the present invention.

FIG. 8 illustrates a process in which a chip-on-wafer is manufactured in accordance with the method of manufacturing a chip-on-wafer for a micro-LED display according to the third embodiment of the present invention.

FIG. 9 is a flowchart of a method of manufacturing a chip-on-wafer for a micro-LED display according to a fourth embodiment of the present invention.

FIG. 10 illustrates a process in which a chip-on-wafer is manufactured in accordance with the method of manufacturing a chip-on-wafer for a micro-LED display according to the fourth embodiment of the present invention.

FIG. 11 illustrates a lateral chip manufactured using the chip-on-wafer manufactured in accordance with the method of manufacturing a chip-on-wafer for a micro-LED display according to the second embodiment of the present invention.

FIG. 12 illustrates a flip chip manufactured using the chip-on-wafer manufactured in accordance with the method of manufacturing a chip-on-wafer for a micro-LED display according to the fourth embodiment of the present invention.

FIG. 13 illustrates a vertical chip manufactured using the chip-on-wafer manufactured in accordance with the method of manufacturing a chip-on-wafer for a micro-LED display according to the first embodiment of the present invention.

FIG. 14 illustrates a vertical chip manufactured using the chip-on-wafer manufactured in accordance with the method of manufacturing a chip-on-wafer for a micro-LED display according to the third embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even though the same components are shown in different drawings

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define an essence, order, or sequence of a corresponding component but used merely to distinguish the corresponding component from other component(s).

Hereinafter, a method (S100) of manufacturing a chip-on-wafer for a micro-light-emitting diode (LED) display according to a first embodiment of the present invention will be described in detail with reference to the accompanying drawings.

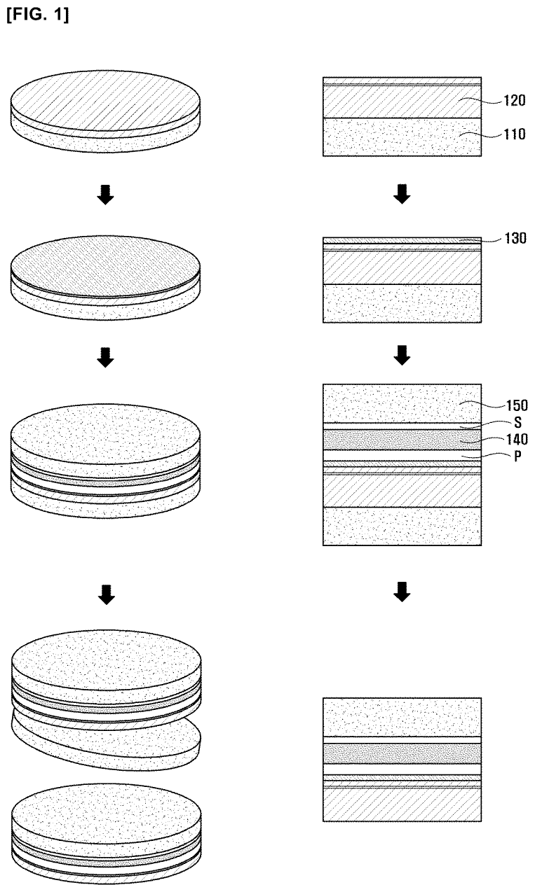

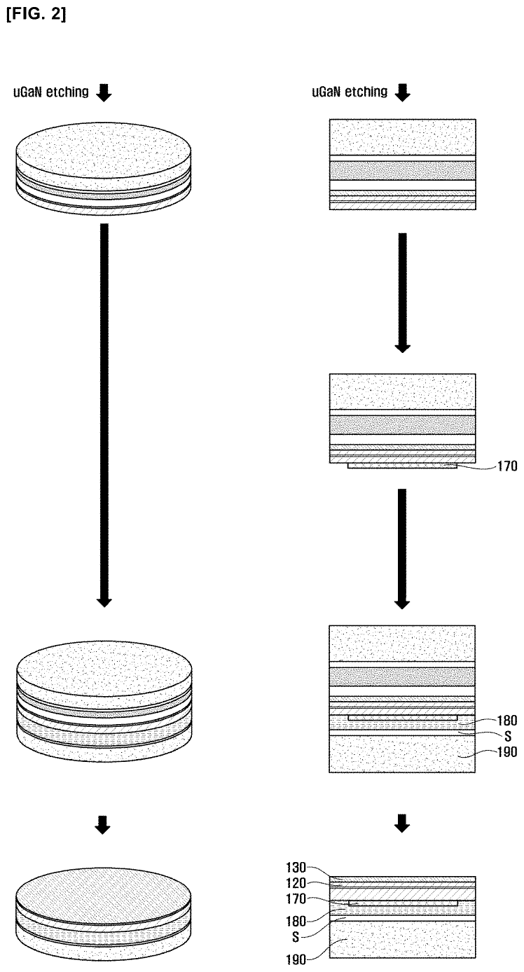

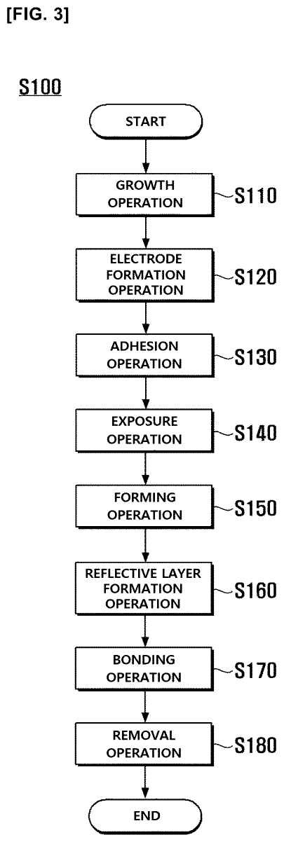

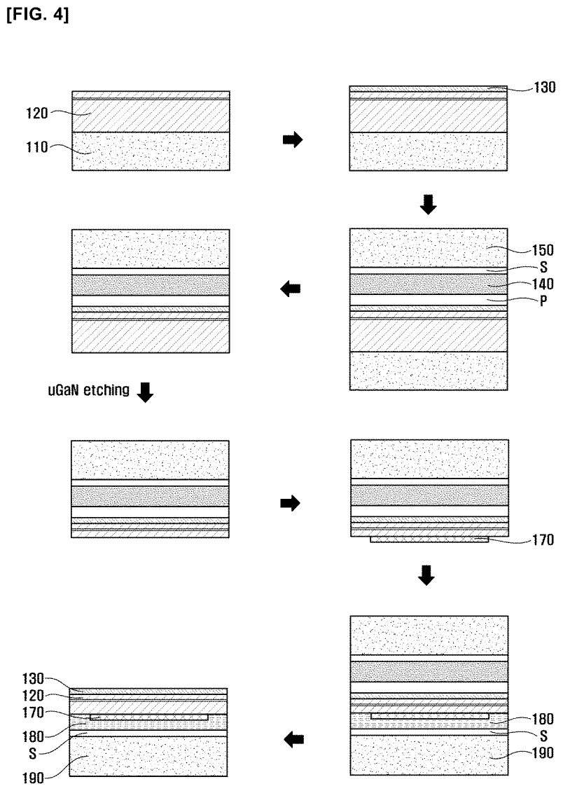

FIGS. 1 and 2 illustrate an overall process in which a chip-on-wafer is manufactured according to a method of manufacturing a chip-on-wafer for a micro-LED display of the present invention, FIG. 3 is a flowchart of a method (S100) of manufacturing a chip-on-wafer for a micro-LED display according to a first embodiment of the present invention, and FIG. 4 illustrates a process in which a chip-on-wafer is manufactured in accordance with the method (S100) of manufacturing a chip-on-wafer for a micro-LED display according to the first embodiment of the present invention.

As shown in FIGS. 1 to 4, in the method (S100) of manufacturing a chip-on-wafer for a micro LED display according to the first embodiment of the present invention, a chip-on-wafer is manufactured through a two-time bonding method, and the method (S100) includes a growth operation S110, an electrode formation operation S120, an adhesion operation S130, an exposure operation S140, a forming operation S150, a reflective layer formation operation S160, a bonding operation S170, and a removal operation S180.

The growth operation S110 is an operation of preparing an initial growth substrate 110 and epitaxially growing a semiconductor layer 120 on the initial growth substrate 110.

When the semiconductor layer 120 emits blue or green light, the initial growth substrate 110 may be provided as a sapphire (α-phase Al₂O₃) substrate that is optically transparent and has high temperature resistance, and allows 100% (theoretical) transmission of a laser beam (single-wavelength light) without absorption when a laser lift-off (LLO) process is used to remove the initial growth substrate 110. When a chemical lift-off (CLO) process is used to remove the initial growth substrate 110, the initial growth substrate 110 may be provided as a silicon (Si) substrate having a (111), (110), or (100) crystal plane that can be removed by wet etching.

Meanwhile, when the initial growth substrate 110 is provided as a sapphire substrate, it is preferable that the initial growth substrate 110 has a protrusion structure patterned regularly or irregularly in various dimensions (size and shape) at the microscale or nanoscale, in order to minimize crystal defects in a Group III nitride semiconductor thin film grown thereon (patterned sapphire substrate, PSS).

In addition, when the semiconductor layer 120 emits red light, the initial growth substrate 110 may be provided as a GaAs substrate that can be removed by wet etching through a chemical lift-off (CLO) process. Furthermore, when the semiconductor layer 120 emits red light through a high-quality InGaN active region with a high In composition of 30% or more, the initial growth substrate 110 may be provided as a sapphire or Si substrate, as in the case in which the semiconductor layer 120 emits blue or green light.

The semiconductor layer 120 generates light and includes a third semiconductor region, a second semiconductor region, an active region, and a first semiconductor region.

In the present invention, the semiconductor layer 120 may emit blue, green, or red light, and when the semiconductor layer 120 emits blue or green light, binary, ternary, or quaternary compounds, such as InN, InGaN, GaN, AlGaN, AIN, or AlGaInN, which are Group III (Al, Ga, and In) nitride semiconductors among Group III-V compound semiconductors, can be epitaxially grown on the initial growth substrate 110 by being placed in appropriate positions and sequences.

In particular, in order to emit blue or green light, a high-quality InGaN Group III nitride semiconductor with a high In composition should preferentially be formed on top (active region) of Group III nitride semiconductors composed of GaN, AlGaN, AlN, or AlGaInN, but the present invention is not limited thereto.

Further, in the present invention, when the semiconductor layer 120 emits red light, binary, ternary, and quaternary compounds such as InP, InGaP, GaP, AlInP, AlGaP, AlP, or AlGaInP, which are Group III (Al, Ga, and In) phosphide semiconductors among Group III-V compound semiconductors, may be epitaxially grown on the initial growth substrate 110 by being placed at appropriate positions and sequence.

In particular, in order to emit red light, a high-quality InGaP Group III phosphide semiconductor with a high In composition should preferentially be formed on top of Group III phosphide semiconductors composed of GaP, AlInP, AlGaP, AlP, or AlGaInP, but the present invention is not limited thereto, and for convenience of description, the following description will be based on Group III nitride semiconductors.

In addition, to further enhance the value of display panel products, along with the recent development of equipment and process technology, when emitting red light, a high-quality InGaN group III nitride semiconductor with a high In composition of 30% or more may be preferentially formed on top (active region) of Group III nitride semiconductors composed of GaN, AlGaN, AlN, or AlGaInN, in addition to group III phosphide semiconductors. Specifically, when the active region is composed of InₓGa₁₋ₓN, the active region emits blue light in a wavelength range of 450 nm to 470 nm when the indium composition, x, is 16% to 20%, emits green light in a wavelength range of 525 nm to 540 nm when the indium composition is 22% to 28%, and emits red light in a wavelength range of 625 nm to 635 nm when the indium composition is 30% to 35% (preferably 33%).

More specifically, in the growth operation S110, a third semiconductor region, which is an un-doped semiconductor region (e.g., uGaN, uInGaN, uAlGaN, or uAlGaInN), a second semiconductor region, which is an n-type semiconductor region (e.g., nGaN, nInGaN, nAlGaN, or nAlGaInN), a multi-quantum well (MQW) active region, and a first semiconductor region, which is a p-type semiconductor region (e.g., pGaN, pInGaN, pAIGaN, or pAlGaInN), may be epitaxially grown in sequence on the initial growth substrate 110, and the resulting structure may include multiple layers of Group III nitrides and typically have an overall thickness of approximately 5.0 to 7.0 μm, but the present invention is not limited thereto. The third semiconductor region is an un-doped semiconductor region.

Specifically, the third semiconductor region is introduced prior to the epitaxial growth of the second semiconductor region, the active region, and the first semiconductor region on the initial growth substrate 110, and serves as a buffer region to relieve stress in the epitaxially grown second semiconductor region, active region, and first semiconductor region and improve the thin-film quality.

The third semiconductor region may include a nucleation layer (NL) and may typically be formed to have a thickness of 2.5 μm to 3 μm. In addition, when the initial growth substrate 110 is removed using a laser lift-off (LLO) technique, a sacrificial layer (SL) may be provided between the nucleation layer and the third semiconductor region, and the nucleation layer may function as the sacrificial layer.

The second semiconductor region has n-type conductivity and is formed on the third semiconductor region. This second semiconductor region may have a thickness of 2.0 to 2.5 μm, and a bottom surface thereof may have nitrogen polarity (N-polarity).

The active region, which has a multi-quantum well structure and generates light through recombination of electrons and holes, is formed on the second semiconductor region. The active region may be formed as multiple layers with a thickness of approximately 50 nm.

The first semiconductor region has p-type conductivity and is formed on the active region. The first semiconductor region may be formed as multiple layers with a thickness of 0.5 μm or less, and a top surface thereof may have gallium polarity (Ga-polarity).

That is, the active region is interposed between the second semiconductor region and the first semiconductor region, and light is generated when electrons from the second semiconductor region, which is an n-type semiconductor region and holes from the first semiconductor region, which is a p-type semiconductor region, recombine within the active region.

The electrode formation operation S120 is an operation of forming an ohmic contact electrode 130 on the semiconductor layer 120.

According to a conventional chip-on-wafer method, since the stacked structure of chips (including lateral chips, flip chips, and vertical chips) is completed using only the initial growth substrate 110, a p-type ohmic contact (p-ohmic contact) electrode 130 must be formed in a back-end process. In this case, since the formation of the p-ohmic contact electrode 130 essentially requires heat treatment at a temperature of 450° C. or higher, there is an issue that the chip, in which a plurality of layers have already been stacked, may be damaged by the high temperature.

Accordingly, in the present invention, after the semiconductor layer 120 is grown in a state in which other layers are not yet stacked (i.e., before the structure of the chip is completed), the p-ohmic contact electrode 130 is formed through high-temperature heat treatment, and then the remaining necessary layers, such as a reflective layer 170, are stacked on one surface of the semiconductor layer 120, thereby fundamentally preventing damage to the chip having a stacked structure, which would be caused by the high-temperature heat treatment for forming the p-ohmic contact electrode 130.

More specifically, in the present invention, the ohmic contact electrode 130 is formed in contact with the first semiconductor region, which is a p-type semiconductor, and thus functions as the p-ohmic contact electrode 130, and since the present embodiment is applied to a vertical chip structure, the p-ohmic contact electrode 130 is formed of a transparent conductive material so that light from the lower side can be transmitted upward.

Meanwhile, in the present invention, the p-ohmic contact electrode 130 may have a single-layer structure, and may also have a multi-layer structure in which the thin p-ohmic contact electrode 130 is first formed on a gallium-polarity (Ga-polarity) surface, and then a p-type electrode made of a material that is the same as or a different from the p-ohmic contact electrode 130 is formed thereon and electrically connected to the underlying p-ohmic contact electrode 130.

The adhesion operation S130 is an operation of bonding the ohmic contact electrode 130 to an intermediate temporary substrate 150 through an adhesive layer 140.

Here, the intermediate temporary substrate 150 preferably has a coefficient of thermal expansion (CTE) that is equal to or similar to those of the initial growth substrate 110 and the final support substrate 190. When a laser lift-off (LLO) process is used to remove the intermediate temporary substrate 150, the substrate may be provided as a sapphire (a-phase Al₂O₃) substrate or as glass whose CTE is controlled to differ from that of the support substrate 190 by 2 ppm or less, both of which are optically transparent and have high temperature resistance, and allow 100% (theoretical) transmission of a laser beam (single-wavelength light) without absorption, and when a chemical lift-off (CLO) process is used to remove the intermediate temporary substrate 150, the substrate may be provided as an Si substrate having a (111), (110), or (100) crystal plane that can be removed by wet etching.

Further, in the present embodiment, the adhesive layer 140 may be formed of a metal or alloy, ceramic, or resin material. In particular, it is preferable that the adhesive layer 140 is preferentially formed of a material suitable for metallic bonding (eutectic bonding, diffusion bonding, direct bonding, and the like), and the adhesive layer 140 may include a metallic bonding material that is solderable at a temperature of 300° C. or lower, and may include materials such as In, Sn, Ga, Zn, Au, Ag, Cu, Pd, Ni, Ti, Cr, Al, or Si. In addition, the adhesive layer 140 may include ceramic materials that allow direct bonding at a temperature of 100° C. or lower, such as SiO₂, spin-on glass (SOG), flowable oxides (FOx), SiNₓ, Al₂O₃, AlN, SiCN, ITO, IZO, or ZnO, and may also include resin materials, such as epoxy, benzocyclobutene (BCB), or polyimide (PI), which are organic adhesives that allow indirect bonding at a temperature of 100° C. or lower.

Meanwhile, in the adhesion operation S130, after a separation layer S is formed on the intermediate temporary substrate 150, the ohmic contact electrode 130 may be bonded to the separation layer S through the adhesive layer 140. The separation layer S is a layer that is sacrificed and separated during the removal of the intermediate temporary substrate 150, and the material thereof may vary depending on whether a laser lift-off (LLO) process or a chemical lift-off (CLO) process is used. Meanwhile, the separation layer S may be positioned above or below the adhesive layer 140 depending on the purpose, and when the adhesive layer 140 performs the function of the separation layer S, the separation layer S may be omitted.

Further, in the adhesion operation S130, after a protective layer P is formed on the ohmic contact electrode 130, the protective layer P may be bonded to the temporary substrate 150 through the adhesive layer 140. The protective layer P serves to protect the device below the ohmic contact electrode 130 when the adhesive layer 140 is removed in a subsequent process. Representative materials for the protective layer P may include SiO₂, SiNx, AlN, or the like, but are not limited thereto, and various materials may be used depending on the method used to remove the adhesive layer 140 (for example, a SiO₂ protective layer P may be used when the adhesive layer 140 is removed using hydrochloric acid). Furthermore, the protective layer P may be omitted when the removal of the adhesive layer 140 does not affect the device.

Furthermore, in the adhesion operation S130, after the separation layer S is formed on the intermediate temporary substrate 150 and the protective layer P is formed on the ohmic contact electrode 130, the protective layer P may be bonded to the separation layer S through the adhesive layer 140.

The exposure operation S140 is an operation of exposing one surface of the semiconductor layer 120 by removing the growth substrate 110.

More specifically, in the exposure operation S140, the initial growth substrate 110 may be removed using a laser lift-off (LLO) process or a chemical lift-off (CLO) process, thereby exposing the third semiconductor region, which is an un-doped semiconductor region, to the outside.

The forming operation S150 is an operation of selectively etching the exposed one surface of the semiconductor layer 120 to form the semiconductor layer 120 to a predetermined thickness.

According to the conventional chip-on-wafer method, since the stacked structure of chips (including lateral chips, flip chips, and vertical chips) is completed using only the initial growth substrate 110, the thickness of the un-doped semiconductor region (e.g., uGaN, uInGaN, uAlGaN, or uAlGaInN) or the n-type semiconductor region (e.g., nGaN, nInGaN, nAlGaN, or nAlGaInN) cannot be adjusted. As a result, it is difficult to manufacture high-quality and high-brightness micro-LEDs with a thickness of 5 μm or less, and the presence of such a thick un-doped semiconductor region leads to a reduction in light extraction efficiency.

Meanwhile, in the conventional chip-on-wafer method, the completed chip may be attached to a TFT glass or an interposer, and then the initial growth substrate 110 on the opposite side may be removed to expose the un-doped semiconductor region (e.g., uGaN, uInGaN, uAlGaN, or uAlGaInN). However, even when etching is attempted on the exposed un-doped semiconductor region, the completed chip may be damaged by the high temperatures and injected gases generated during the etching process.

Furthermore, when the initial growth substrate 110 is removed by a laser lift-off (LLO) process, numerous gallium (Ga) droplets (solid or powder) that interfere with the scattering of generated light are generated on the surface of the semiconductor layer 120 from which the initial growth substrate 110 has been removed. Currently, hydrochloric acid vapor or taping is used to remove the gallium (Ga) droplets, but when the hydrochloric acid vapor is used, there are issues that the process results in excessively high costs and the chip can be damaged during the gallium (Ga) droplet removal process, and when the taping is used, there is an issue that complete removal of the gallium (Ga) droplets is not possible. However, in the case of removing the growth substrate for micro-LEDs using a chemical lift-off (CLO) process, such as Si (nitrides emitting blue, green, and red light) or GaAs (phosphides emitting red light), there is no issue related to gallium (Ga) droplets.

Accordingly, in the present invention, the ohmic contact electrode 130 on the semiconductor layer 120 is bonded to the intermediate temporary substrate 150, and then, in a state in which other layers are not yet stacked (i.e., before the chip structure is completed), the initial growth substrate 110 is removed so that the exposed un-doped semiconductor region (e.g., uGaN, uInGaN, uAlGaN, or uAlGaInN) can be formed to a predetermined thickness through etching. This makes it possible to form the un-doped semiconductor region (e.g., uGaN, uInGaN, uAlGaN, or uAlGaInN) to a desired thickness without damaging the chip, thereby enabling the manufacture of high-quality and high-brightness micro-LED display chips having a thickness of 3 μm or less, and fundamentally preventing the gallium (Ga) droplets from remaining on the surface of the semiconductor layer 120, which significantly improves light extraction efficiency.

More specifically, in the forming operation S150, the third semiconductor region, which is an un-doped semiconductor region exposed by the removal of the growth substrate 110, is etched to form the semiconductor layer 120 to a predetermined thickness. In the forming operation S150, the third semiconductor region having a thickness of 2.5 μm to 3 μm may be etched to a desired thickness or entirely removed using a dry process using known gases (such as Cl₂, BCl₃, and Ar plasma), and according to the present invention, even when a high temperature is generated during the etching of the third semiconductor region, the thickness of the chip can be adjusted as desired without damaging the chip, since only the semiconductor layer 120 and the ohmic contact electrode 130 have been formed and the chip structure is not yet completed, thereby providing the advantage that the gallium (Ga) droplets can be completely removed through the etching process.

The reflective layer formation operation S160 is an operation of forming the reflective layer 170 on the one surface of the semiconductor layer 120 that is exposed and etched.

The reflective layer 170 may be formed of Ag, Al, Au, Pd, Pt, Ni, Mo, Cu, Cr, Ti, TiW, ITO, IZO, ZnO, TiN, a distributed Bragg reflector (DBR), an omni-directional reflector (ODR), or a combination thereof, and in the present embodiment, the reflective layer 170 may be formed on one surface of the semiconductor layer 120, that is, the nitrogen-polar (N-polar) surface.

Meanwhile, the reflective layer 170 may have a single-layer structure that functions as an n-type ohmic contact (n-ohmic contact) electrode, or may have a multi-layer structure in which a thin n-ohmic contact electrode is first formed on the nitrogen-polar (N-polar) surface of the semiconductor layer 120, and the reflective layer 170 is subsequently formed thereon using a material that is the same as or different from the n-type ohmic contact electrode, and electrically connected.

Meanwhile, in the present invention, the reflective layer 170 may be formed over the entire nitrogen-polar (N-polar) surface of the semiconductor layer 120 or separately on a per-chip basis, and as shown in FIG. 4, in order to prevent re-deposition from occurring during the etching process for chip-level separation on the chip-on-wafer, it is preferable that the reflective layer 170 is individually formed for each chip using a photoresist (PR).

The bonding operation S170 is an operation of bonding the one surface of the semiconductor layer 120, on which the reflective layer 170 is formed, to the final support substrate 190 through a bonding layer 180.

Here, the final support substrate 190 is a substrate that supports the chip structure obtained through the respective operations of the method (S100) of manufacturing a chip-on-wafer for a micro-LED display according to the first embodiment of the present invention. The support substrate 190 may be provided as a sapphire (a-phase Al₂O₃) substrate or a glass substrate having a controlled coefficient of thermal expansion (CTE).

In the present embodiment, the bonding layer 180 may be formed of a ceramic, resin, or metal or alloy material. In particular, it is preferable that the bonding layer 180 is preferentially selected from ceramic or resin materials. The bonding layer 180 may include ceramic materials that enable direct bonding at temperatures of 100° C. or lower, such as SiO₂, spin-on-glass (SOG), flowable oxides (FOx), SiNx, Al₂O₃, AlN, SiCN, ITO, IZO, or ZnO, and may also include resin materials, such as epoxy, benzocyclobutene (BCB), or polyimide (PI), which enable indirect bonding at temperatures of 100° C. or lower. In addition, the bonding layer 180 may include metallic bonding materials that enable soldering at temperatures of 300° C. or lower, such as In, Sn, Ga, Zn, Au, Ag, Cu, Pd, Ni, Ti, Cr, Al, or Si. Furthermore, when the reflective layer 170 is individually formed on a per-chip basis, the bonding layer 180 may be formed to enclose the reflective layer 170, thereby bonding one surface of the semiconductor layer 120, on which the reflective layer 170 is formed, to the support substrate 190. Here, the bonding layer 180 is not in ohmic contact with the semiconductor layer 120.

Meanwhile, in the bonding operation S170, after the separation layer S is formed on the support substrate 190, the one surface of the semiconductor layer 120 may be bonded to the separation layer S. The separation layer S is a layer that is sacrificed and separated during the removal of the support substrate 190, and a material suitable for a laser lift-off (LLO) process may be used for this purpose. Meanwhile, the separation layer S may be positioned above or below the bonding layer 180 depending on the purpose, and when the bonding layer 180 performs the function of the separation layer S, the separation layer S may be omitted.

The removal operation S180 is an operation of removing the intermediate temporary substrate 150 and the adhesive layer 140.

More specifically, in the removal operation S180, the intermediate temporary substrate 150 and the adhesive layer 140 are removed using a laser lift-off (LLO) process or a chemical lift-off (CLO) process, and when the separation layer S and the protective layer P are formed, the separation layer S and the protective layer P may also be removed together.

As described above, the chip-on-wafer manufactured in accordance with the method (S100) of manufacturing a chip-on-wafer for a micro-LED display according to the first embodiment of the present invention has a structure in which the final support substrate 190, the separation layer S, the bonding layer 180, the reflective layer 170, the semiconductor layer 120, and the ohmic contact electrode 130 are sequentially stacked.

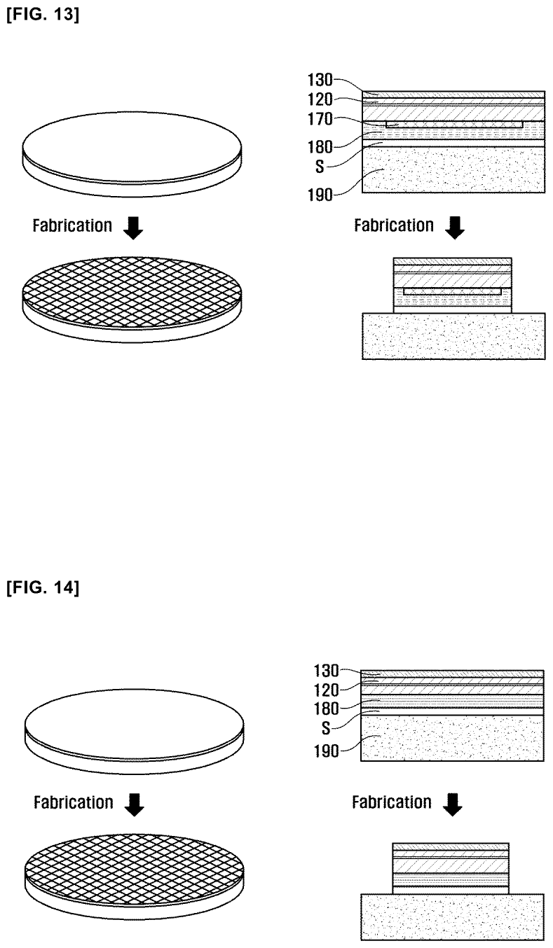

FIG. 13 illustrates a vertical chip manufactured using the chip-on-wafer manufactured in accordance with the method (S100) of manufacturing a chip-on-wafer for a micro-LED display according to the first embodiment of the present invention.

As shown in FIG. 13, when a fabrication (Fab) process is performed on the chip-on-wafer manufactured in accordance with the method (S100) of manufacturing a chip-on-wafer for a micro-LED display according to the first embodiment of the present invention, which has a structure in which the final support substrate 190, the separation layer S, the bonding layer 180, the reflective layer 170, the semiconductor layer 120, and the ohmic contact electrode 130 are sequentially stacked, a vertical chip can be manufactured on the wafer, with the p-ohmic contact electrode 130 provided on the upper side and the reflective layer 170, functioning as an n-ohmic contact electrode, provided on the lower side.

Subsequently, when transferring the chip to a panel, an interposer, or the like to finally manufacture the display, the transfer may be selectively performed using a one-time bonding method or a two-time bonding method, depending on the placement position of a layer (or electrode) functioning as a reflector such as the reflective layer 170, and since the chip manufactured through the present embodiment has a vertical chip structure in which the p-ohmic contact electrode 130 is provided on the upper side and the reflective layer 170, functioning as an n-ohmic contact electrode, is provided on the lower side, through a two-time bonding method using another temporary substrate, the final support substrate 190 is removed and then the panel is positioned on the surface from which the final support substrate 190 has been removed.

Hereinafter, a method (S200) of manufacturing a chip-on-wafer for a micro-LED display according to a second embodiment of the present invention will be described in detail with reference to the accompanying drawings.

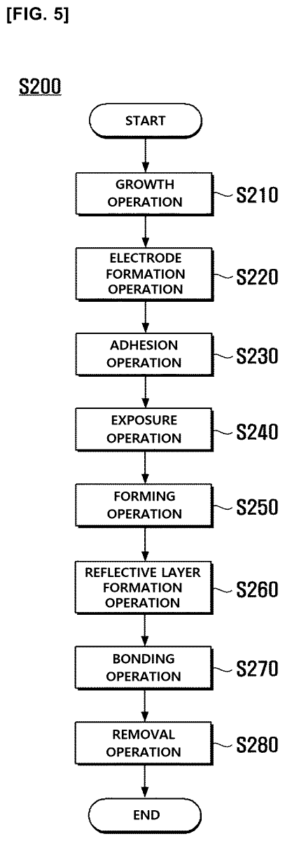

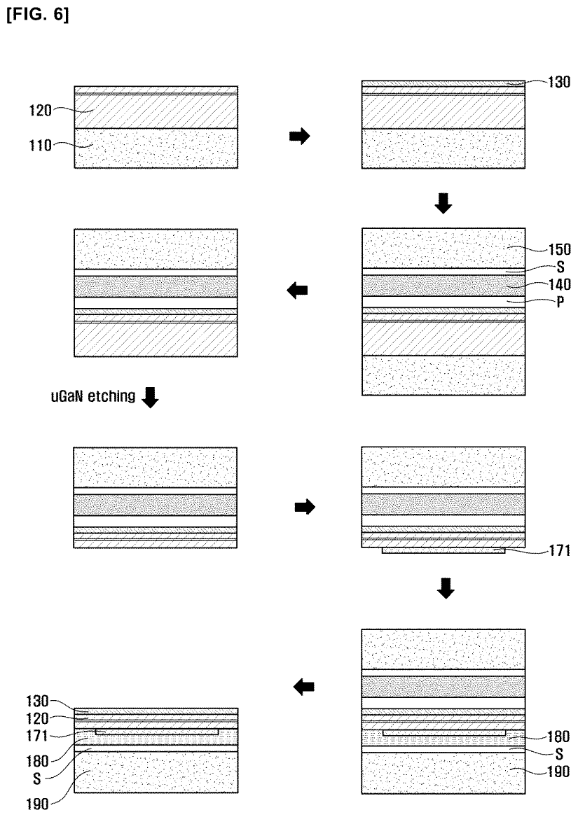

FIG. 5 is a flowchart illustrating the method (S200) of manufacturing a chip-on-wafer for a micro-LED display according to the second embodiment of the present invention, and FIG. 6 illustrates a process in which a chip-on-wafer is manufactured in accordance with the method (S200) of manufacturing a chip-on-wafer for a micro-LED display according to the second embodiment of the present invention.

As shown in FIGS. 5 and 6, in the method (S200) of manufacturing a chip-on-wafer for a micro LED display according to the second embodiment of the present invention, a chip-on-wafer is manufactured through a two-time bonding method, and the method (S200) includes a growth operation S210, an electrode formation operation S220, an adhesion operation S230, an exposure operation S240, a forming operation S250, a reflective layer formation operation S260, a bonding operation S270, and a removal operation S280.

Here, the growth operation S210 is the same as that in the method (S100) of manufacturing a chip-on-wafer for a micro-LED display according to the first embodiment of the present invention described above, and thus redundant descriptions will be omitted.

The electrode formation operation S220 is an operation of forming an ohmic contact electrode 130 on a semiconductor layer 120.

More specifically, in the present invention, the ohmic contact electrode 130 is formed in contact with a first semiconductor region, which is a p-type semiconductor, and thus functions as a p-ohmic contact electrode 130, and since the present embodiment is applied to a lateral chip structure, the ohmic contact electrode 130 is formed of a transparent conductive material so that light from the lower side can be transmitted upward. In this case, the material for the ohmic contact electrode 130 may include NiO, PtO, PdO, AgO₂, Au, Rh₂O₃, RuO₂, In₂O₃, SnO₂, ZnO, IZO, ITO, IGZO, or the like.

The adhesion operation S230 to the forming operation S250 are the same as those in the method (S100) of manufacturing a chip-on-wafer for a micro LED display according to the first embodiment of the present invention described above, and thus redundant descriptions will be omitted.

The reflective layer formation operation S260 is an operation of forming a reflective layer 171 on one surface of the semiconductor layer 120 that is exposed and etched The reflective layer 171 may be formed of Ag, Al, Au, Pd, Pt, Ni, Mo, Cu, Cr, Ti, TiW, ITO, IZO, ZnO, TiN, a distributed Bragg reflector (DBR), an omni-directional reflector (ODR), or a combination thereof, and in the present embodiment, the reflective layer 171 may be formed on one surface of the semiconductor layer 120, which is an n-type semiconductor, that is, a nitrogen-polar (N-polar) surface. Meanwhile, in the present embodiment, the reflective layer 171 is not in ohmic contact with the semiconductor layer 120, and no separate n-ohmic contact electrode is provided in the chip-on-wafer manufactured according to the present embodiment.

Meanwhile, in the present invention, the reflective layer 170 may be formed over the entire nitrogen-polar (N-polar) surface of the semiconductor layer 120 or separately on a per-chip basis, and as shown in FIG. 4, in order to prevent re-deposition during etching for chip-level separation on the chip-on-wafer, it is preferable that the reflective layer 170 is individually formed for each chip using a photoresist (PR).

The bonding operation S270 and the removal operation S280 are the same as those in the method (S100) of manufacturing a chip-on-wafer for a micro LED display according to the first embodiment of the present invention described above, and thus redundant descriptions will be omitted.

As described above, the chip-on-wafer manufactured in accordance with the method (S200) of manufacturing a chip-on-wafer for a micro-LED display according to the second embodiment of the present invention has a structure in which the final support substrate 190, the separation layer S, the bonding layer 180, the reflective layer 171, the semiconductor layer 120, and the ohmic contact electrode 130 are sequentially stacked.

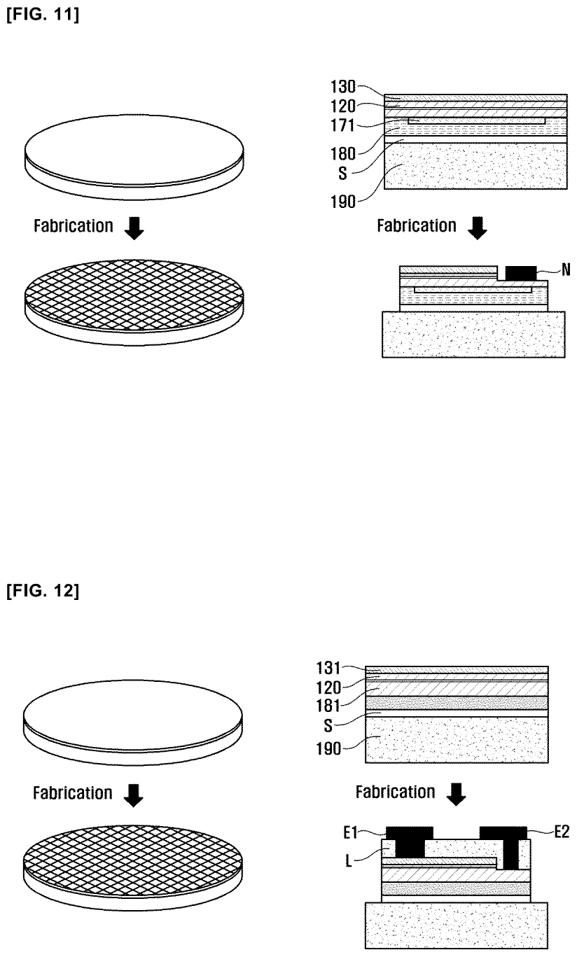

FIG. 11 illustrates a lateral chip manufactured using the chip-on-wafer manufactured in accordance with the method (S200) of manufacturing a chip-on-wafer for a micro-LED display according to the second embodiment of the present invention.

As shown in FIG. 11, when a fabrication (Fab) process is performed on the chip-on-wafer manufactured in accordance with the method (S200) of manufacturing a chip-on-wafer for a micro-LED display according to the second embodiment of the present invention, which has a structure in which the final support substrate 190, the separation layer S, the bonding layer 180, the reflective layer 171, the semiconductor layer 120, and the ohmic contact electrode 130 are sequentially stacked, a portion of the semiconductor layer 120 is subjected to mesa etching, and an n-ohmic contact electrode N is formed on a second semiconductor region, which is an n-type semiconductor, and thus a lateral chip provided with both the p-ohmic contact electrode 130 and the n-ohmic contact electrode N on the upper side thereof can be manufactured on the wafer.

Subsequently, when transferring the chip to a panel, an interposer, or the like to finally manufacture the display, the transfer may be selectively performed using a one-time bonding method or a two-time bonding method, depending on the placement position of a layer (or electrode) functioning as a reflector such as the reflective layer 170, and since the chip manufactured through the present embodiment has a lateral chip structure in which the p-ohmic contact electrode 130 and the n-ohmic contact electrode N are provided on the upper side, through a two-time bonding method using another temporary substrate, the final support substrate 190 is removed and then the panel is positioned on the surface from which the final support substrate 190 has been removed.

Hereinafter, a method (S300) of manufacturing a chip-on-wafer for a micro-LED display according to a third embodiment of the present invention will be described in detail with reference to the accompanying drawings.

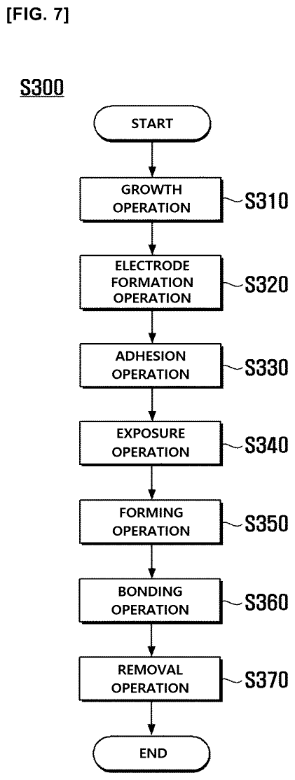

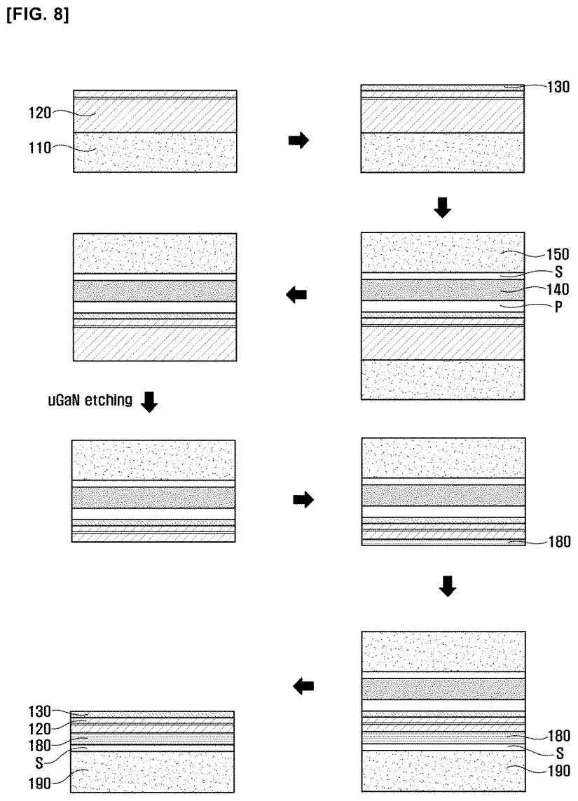

FIG. 7 is a flowchart illustrating the method (S300) of manufacturing a chip-on-wafer for a micro-LED display according to the third embodiment of the present invention, and FIG. 8 illustrates a process in which a chip-on-wafer is manufactured in accordance with the method (S300) of manufacturing a chip-on-wafer for a micro-LED display according to the third embodiment of the present invention.

As shown in FIGS. 7 and 8, in the method (S300) of manufacturing a chip-on-wafer for a micro LED display according to the third embodiment of the present invention, a chip-on-wafer is manufactured through a two-time bonding method, and the method (S300) includes a growth operation S310, an electrode formation operation S320, an adhesion operation S330, an exposure operation S340, a forming operation S350, a bonding operation S360, and a removal operation S370.

Here, the growth operation S310 is the same as that in the method (S100) of manufacturing a chip-on-wafer for a micro-LED display according to the first embodiment of the present invention described above, and thus redundant descriptions will be omitted.

The electrode formation operation S320 is an operation of forming an ohmic contact electrode 130 on a semiconductor layer 120.

More specifically, in the present invention, the ohmic contact electrode 130 is formed in contact with the first semiconductor region, which is a p-type semiconductor, and thus functions as a p-ohmic contact electrode 130, and since the present embodiment is applied to a vertical chip structure, the p-ohmic contact electrode 130 is formed of a transparent conductive material so that light from the lower side can be transmitted upward. In this case, the material for the ohmic contact electrode 130 may include NiO, PtO, PdO, AgO₂, Au, Rh₂O₃, RuO₂, In₂O₃, SnO₂, ZnO, IZO, ITO, IGZO, and the like.

The adhesion operation S330 to the forming operation S350 are the same as those in the method (S100) of manufacturing a chip-on-wafer for a micro LED display according to the first embodiment of the present invention described above, and thus redundant descriptions will be omitted.

The bonding operation S360 is an operation of bonding one surface of the semiconductor layer 120, that is, a nitrogen-polar (N-polar) surface, to a final support substrate 190 through a bonding layer 180.

Here, the final support substrate 190 is a substrate that supports the chip structure obtained through the respective operations of the method (S300) of manufacturing a chip-on-wafer for a micro-LED display according to the third embodiment of the present invention.

The support substrate 190 may be provided as a sapphire (a-phase Al₂O₃) substrate or a glass substrate having a controlled coefficient of thermal expansion (CTE). In addition, in the present embodiment, the bonding layer 180 may be formed of a metal material and may include metallic bonding materials that allow soldering at temperatures of 300° C. or lower, such as In, Sn, Ga, Zn, Au, Ag, Cu, Pd, Ni, Ti, Cr, Al, or Si. In the present embodiment, the bonding layer 180 may be in n-ohmic contact with one surface of the semiconductor layer 120, which is an n-type semiconductor, and may also serve as a reflector.

Meanwhile, in the bonding operation S360, after a separation layer S is formed on the support substrate 190, the one surface of the semiconductor layer 120 may be bonded to the separation layer S. The separation layer S is a layer that is sacrificed and separated during the removal of the support substrate 190, and a material suitable for a laser lift-off (LLO) process may be used for this purpose. Meanwhile, the separation layer S may be positioned above or below the bonding layer 180 depending on the purpose, and when the bonding layer 180 performs the function of the separation layer S, the separation layer S may be omitted.

Here, the removal operation S370 is the same as that in the method (S100) of manufacturing a chip-on-wafer for a micro LED display according to the first embodiment of the present invention described above, and thus redundant descriptions will be omitted.

As described above, the chip-on-wafer manufactured in accordance with the method (S300) of manufacturing a chip-on-wafer for a micro-LED display according to the first embodiment of the present invention has a structure in which the final support substrate 190, the separation layer S, the bonding layer 180, the semiconductor layer 120, and the ohmic contact electrode 130 are sequentially stacked.

FIG. 14 illustrates a vertical chip manufactured using the chip-on-wafer manufactured in accordance with the method (S300) of manufacturing a chip-on-wafer for a micro-LED display according to the third embodiment of the present invention.

As shown in FIG. 14, when a fabrication (Fab) process is performed on the chip-on-wafer manufactured in accordance with the method (S300) of manufacturing a chip-on-wafer for a micro-LED display according to the third embodiment of the present invention, which has a structure in which the final support substrate 190, the separation layer S, the bonding layer 180, the semiconductor layer 120, and the ohmic contact electrode 130 are sequentially stacked, a vertical chip can be manufactured on the wafer, with the p-ohmic contact electrode 130 provided on the upper side and the bonding layer 180, functioning as an n-ohmic contact electrode, provided on the lower side.

Subsequently, when transferring the chip to a panel, an interposer, or the like to finally manufacture the display, the transfer may be selectively performed using a one-time bonding method or a two-time bonding method, depending on the placement position of a layer (or electrode) functioning as a reflector such as the reflective layer 170, and since the chip manufactured through the present embodiment has a vertical chip structure in which the p-ohmic contact electrode 130 is provided on the upper side and the bonding layer 180, functioning as an n-ohmic contact electrode, is provided on the lower side, through a two-time bonding method using another temporary substrate, the final support substrate 190 is removed and then the panel is positioned on the surface from which the final support substrate 190 has been removed.

Hereinafter, a method (S400) of manufacturing a chip-on-wafer for a micro-LED display according to a fourth embodiment of the present invention will be described in detail with reference to the accompanying drawings.

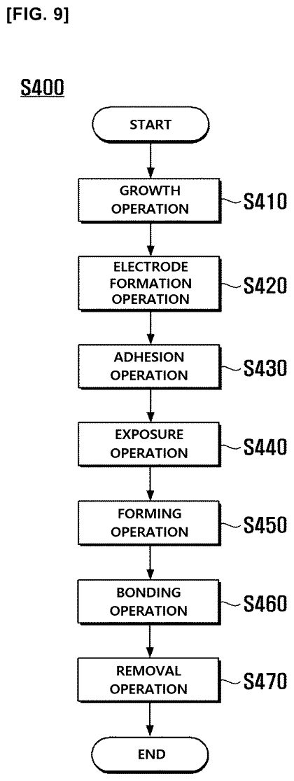

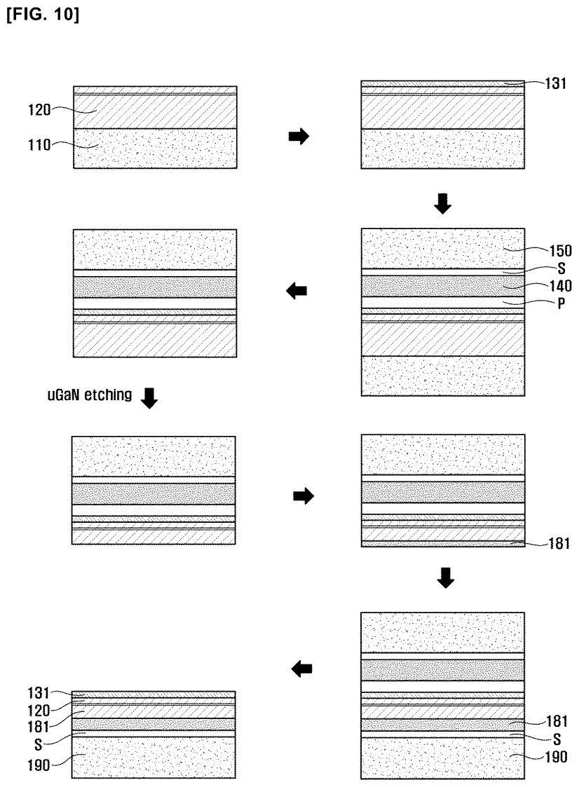

FIG. 9 is a flowchart illustrating the method (S400) of manufacturing a chip-on-wafer for a micro-LED display according to the fourth embodiment of the present invention, and FIG. 10 illustrates a process in which a chip-on-wafer is manufactured in accordance with the method (S400) of manufacturing a chip-on-wafer for a micro-LED display according to the fourth embodiment of the present invention.

As shown in FIGS. 9 and 10, in the method (S400) of manufacturing a chip-on-wafer for a micro LED display according to the fourth embodiment of the present invention, a chip-on-wafer is manufactured through a two-time bonding method, and the method (S400) includes a growth operation S410, an electrode formation operation S420, an adhesion operation S430, an exposure operation S440, a forming operation S450, a bonding operation S460, and a removal operation S470.

Here, the growth operation S410 is the same as that in the method (S100) of manufacturing a chip-on-wafer for a micro-LED display according to the first embodiment of the present invention described above, and thus redundant descriptions will be omitted.

The electrode formation operation S420 is an operation of forming an ohmic contact electrode 131 on a semiconductor layer 120.

More specifically, in the present invention, the ohmic contact electrode 131 is formed in contact with a first semiconductor region, which is a p-type semiconductor, and thus functions as a p-ohmic contact electrode 131, and since the present embodiment is applied to a flip chip structure, the ohmic contact electrode 131 is formed of a metallic material so as to reflect generated light. In this case, the material for the ohmic contact electrode 131 may include Ag, Al, Au, Pt, Ni, Mo, Cu, Cr, Ti, and the like (note: Ag is not in direct ohmic contact, but the thin p-ohmic contact electrode 130 made of another material may first be formed on the gallium-polar (Ga-polarity) surface, and Ag may then be formed thereon).

Meanwhile, in the present embodiment, the ohmic contact electrode 131 may also be formed of a transparent conductive material, and in this case, the material for the ohmic contact electrode 131 may include TiW, ITO, IZO, and the like. Although not shown in the drawings, a separate reflector may also be provided on the transparent conductive ohmic contact electrode 131 so as to reflect generated light.

The adhesion operation S430 to the forming operation S450 are the same as those in the method (S100) of manufacturing a chip-on-wafer for a micro LED display according to the first embodiment of the present invention described above, and thus redundant descriptions will be omitted.

The bonding operation S460 is an operation of bonding one surface of the semiconductor layer 120 to a final support substrate 190 through a bonding layer 181.

Here, the final support substrate 190 is a substrate that supports the chip structure obtained through the respective operations of the method (S400) of manufacturing a chip-on-wafer for a micro-LED display according to the fourth embodiment of the present invention. The support substrate 190 may be provided as a sapphire (a-phase Al₂O₃) substrate or a glass substrate having a controlled coefficient of thermal expansion (CTE).

In addition, in the present embodiment, the bonding layer 181 may include flowable oxides (FOx) such as SiO₂, SiNx, SiCN, AlN, Al₂O₃, spin-on-glass (SOG, liquid-phase SiO₂), or hydrogen silsesquioxane (HSQ), so that the generated light can be transmitted therethrough, and in the present embodiment, the bonding layer 181 is formed on one surface of the semiconductor layer 120, which is an n-type semiconductor, but is not in ohmic contact therewith.

Meanwhile, in the bonding operation S460, after a separation layer S is formed on the support substrate 190, the one surface of the semiconductor layer 120 may be bonded to the separation layer S. The separation layer S is a layer that is sacrificed and separated during the removal of the support substrate 190, and a material suitable for a laser lift-off (LLO) process may be used for this purpose. Meanwhile, the separation layer S may be positioned above or below the bonding layer 181 depending on the purpose, and when the bonding layer 181 performs the function of the separation layer S, the separation layer S may be omitted.

Here, the removal operation S470 is the same as that in the method (S100) of manufacturing a chip-on-wafer for a micro LED display according to the first embodiment of the present invention described above, and thus redundant descriptions will be omitted.

As described above, the chip-on-wafer manufactured in accordance with the method (S400) of manufacturing a chip-on-wafer for a micro-LED display according to the fourth embodiment of the present invention has a structure in which the final support substrate 190, the separation layer S, the bonding layer 181, the semiconductor layer 120, and the ohmic contact electrode 131 are sequentially stacked.

FIG. 12 illustrates a flip chip manufactured using the chip-on-wafer manufactured in accordance with the method (S400) of manufacturing a chip-on-wafer for a micro-LED display according to the fourth embodiment of the present invention.

As shown in FIG. 12, when a fabrication (Fab) process is performed on the chip-on-wafer manufactured in accordance with the method (S400) of manufacturing a chip-on-wafer for a micro-LED display according to the fourth embodiment of the present invention, which has a structure in which the final support substrate 190, the separation layer S, the bonding layer 181, the semiconductor layer 120, and the ohmic contact electrode 131 are sequentially stacked, after a portion of the semiconductor layer 120 is subjected to mesa etching, an n-ohmic contact electrode (not shown) and a passivation layer L are formed, and then a plurality of through-holes are formed in the passivation layer L to form a first extension electrode E1 that is electrically connected to the p-ohmic contact electrode 131 and a second extension electrode E2 that is electrically connected to the n-ohmic contact electrode (not shown) at the mesa-etched portion, and thus a flip chip can be manufactured on the wafer. Here, the n-ohmic contact electrode may be formed without heat treatment, and the second extension electrode E2 may be directly connected to the semiconductor layer 120 at the mesa-etched portion after the n-ohmic contact electrode is omitted.

Subsequently, when transferring the chip to a panel, an interposer, or the like for to finally manufacture the display, the transfer may be selectively performed using a one-time bonding method or two-time bonding method, depending on the placement position of a layer (or electrode) functioning as a reflector, such as the reflective layer 170, and since the chip manufactured through the present embodiment has a flip chip structure which does not include a reflective layer 170 and in which the p-ohmic contact electrode 130 functions as a reflector (or a reflector placed on the transparent conductive p-ohmic contact electrode 130 performs the reflective function), after the first extension electrode E1 and the second extension electrode E2 are bonded to the panel through a one-time bonding method, the final support substrate 190 is removed.

Although all the components constituting the embodiments of the present invention have been described as being combined into one or being operated in a combined state, the present invention is not essentially limited to the embodiments. That is, all the components may be selectively combined and operated as one or more components within the scope of the present invention.

Further, because the terms, such as “comprising,” “including,” or “having” may mean that the corresponding component may be included unless there is a specially contradictory description, it should be construed that another component is not extruded but may be further included. Unless defined otherwise, all terms used herein, including technical or scientific terms, have the same meanings as those generally understood by those skilled in the art to which the present invention pertains. The terms, such as the terms defined in dictionaries, which are generally used, should be construed to coincide with the context meanings of the related technologies, and are not construed as ideal or excessively formal meanings unless explicitly defined in the present invention.

In addition, the above description is a simple exemplification of the technical spirits of the present invention, and the present invention may be variously corrected and modified by those skilled in the art to which the present invention pertains without departing from the essential features of the present invention.

Accordingly, the embodiments disclosed in the present invention are not provided to limit the technical spirits of the embodiments of the present invention but provided to describe the present invention, and the scope of the technical spirits of the present invention is not limited by the embodiments. The scope of protection of the present invention should be construed by the attached claims, and all the technical spirits within the equivalent ranges fall within the scope of the present invention.

1. A method of manufacturing a chip-on-wafer for a micro-light-emitting diode (LED) display, the method comprising:
a growth operation of epitaxially growing a semiconductor layer on a growth substrate;
an electrode formation operation of forming an ohmic contact electrode on the semiconductor layer;
an adhesion operation of bonding the ohmic contact electrode to a temporary substrate through an adhesive layer;
an exposure operation of exposing one surface of the semiconductor layer by removing the growth substrate;
a bonding operation of bonding the exposed one surface of the semiconductor layer to a support substrate; and
a removal operation of removing the temporary substrate and the adhesive layer.

2. The method of claim 1, further comprising a forming operation of etching the exposed one surface of the semiconductor layer to form the semiconductor layer to a predetermined thickness.

3. The method of claim 2, wherein
in the growth operation, a third semiconductor region, a second semiconductor region, an active region, and a first semiconductor region are epitaxially grown in sequence,
in the forming operation, the third semiconductor region, which is exposed, is etched to form the semiconductor layer to the predetermined thickness, and
the third semiconductor region is an un-doped semiconductor region.

4. The method of claim 1, further comprising a reflective layer formation operation of forming a reflective layer on the exposed one surface of the semiconductor layer,
wherein, in the bonding operation, the one surface of the semiconductor layer on which the reflective layer is formed is bonded to the support substrate through a bonding layer.

5. The method of claim 4, wherein the reflective layer is in ohmic contact with the one surface of the semiconductor layer.

6. The method of claim 1, wherein, in the bonding operation, the one surface of the semiconductor layer is bonded to the support substrate through a bonding layer.

7. The method of claim 6, wherein the bonding layer is in ohmic contact with the one surface of the semiconductor layer.

8. The method of claim 1, wherein, in the bonding operation, after a separation layer is formed on the support substrate, the one surface of the semiconductor layer is bonded to the separation layer.

9. The method of claim 1, wherein, in the adhesion operation, after a separation layer is formed on the temporary substrate, the ohmic contact electrode is bonded to the separation layer through the adhesive layer.

10. The method of claim 1, wherein, in the adhesion operation, after a protective layer is formed on the ohmic contact electrode, the protective layer is bonded to the temporary substrate through the adhesive layer.
